(19) United States
(12) Patent Application Publication
(10) Pub. No.: US 2017/0211178 A9
(43) Pub. Date: Jul. 27, 2017

(54) SURFACE TREATMENT METHOD WITH SUPERIOR MASS-PRODUCTIVITY AND LOW FRICTION CHARACTERISTICS

(71) Applicant: Hyundai Motor Company, Seoul (KR)

(72) Inventors: Woong Pyo Hong, Seoul (KR); Jung Yeon Park, Yongin (KR); Kwang Hoon Choi, Yongin (KR); Bo Kyung Kim, Yongin (KR); In Woong Lyo, Suwon (KR); Ji Youn Seo, Suwon (KR)

(21) Appl. No.: 14/886,825

(22) Filed: Oct. 19, 2015

(30) Foreign Application Priority Data
Dec. 3, 2014 (KR) 10-2014-0172411

(51) Int. Cl. C23C 14/35; C23C 14/34; C23C 14/50; C23C 14/06

(52) U.S. Cl. CPC C23C 14/35; C23C 14/0641; C23C 14/3464; C23C 14/505

(57) ABSTRACT

Provided is a surface treatment method, including: preparing a composite comprising chromium (Cr) of about 95 to 98 atomic percents and copper (Cu) of about 2 to 5 atomic percents with respect to the total number of atoms in the composite; and forming a coating layer comprising Cr of about 30 to 40 atomic, Cu of about 2 to 5 atomic percents, with respect to the total number of atoms of the coating layer, and N constituting the balance of the atoms of the coating layer, by sputtering from the composite in a nitrogen-containing atmospheric gas. Further, provided is a vehicle part, surface of which is treated with the same method.

### CROSS-REFERENCE TO RELATED APPLICATION

This application is based on and claims the benefit of priority to Korean Patent Application No. 10-2014-0172411, filed on Dec. 3, 2014 in the Korean Intellectual Property Office, the disclosure of which is incorporated herein in its entirety by reference.

### TECHNICAL FIELD

The present invention relates to a method for surface treatment by forming a composite coating layer comprising chromium (Cr), copper (Cu), and nitrogen (N), and a vehicle engine part that is manufactured by the same method. In particular, by the method for surface treatment of the present invention, the composite coating layer may be applied on a product with substantially improved adhesion and hardness, low coefficient of friction, and the production thereof may be efficiently performed.

### BACKGROUND

A diamond like carbon (DLC) has been recently used as a coating material of an engine driving part, and low dry/wet friction and wear resistance at room temperature thereof are excellent. However, wear resistance and low friction characteristic at high temperature of the DLC are deteriorated and has inferior durability. Further, adhesion property with a base material is also inferior due to high residual stress, and thus, the DLC material requires additional processes or material, such as an interlayer. In addition, when applying the DLC coating material, cost may be raised by long processing time due to a low sputtering rate of carbon.

Meanwhile, chromium nitride (CrN) has been used for a long time as a sliding member used for sliding with iron metal, or the like, of a relative member or sliding between coated films. Particularly, a technology in the related arts of forming chromium nitride coating layers on surfaces of a vane, a roller, a shaft of a rotary compressor has been used. However, since CrN still does not provide sufficient friction characteristic, hardness, or adhesion property of a material used for coating a surface of vehicle engine driving parts. Alternatively, a chromium (Cr)-copper (Cu)-nitrogen (N) composite coating material with increased lubrication and mechanical characteristics by adding copper (Cu) in a CrN coating material has been designed as a substitute for CrN.

When the Cr—Cu—N coating material is applied by hybrid physical vapor deposition (PVD) which is a generally used method in the related art, the interlayer may not be required due to superior lubrication and mechanical characteristics and high adhesion. However, co-deposition of at least two different source elements needs to be performed, such that a coated region may be restricted, which may further prevent mass-productivity.

Therefore, a research into a surface treatment method capable of having superior lubrication and mechanical characteristics, and achieving mass-production without requiring additional processes for an interlayer due to high close adhesion, is in an urgent need.

### SUMMARY

In preferred aspects, the present invention provides a method for surface treatment, or a surface treatment method that is capable of overcoming above-described disadvantages of a diamond like carbon (DLC) coating method according to the related art, such as production time delay and rise in cost. In addition, the surface treatment method may improve efficiency of mass-production in a chromium (Cr)-copper (Cu)-nitrogen (N) coating method by hybrid physical vapor deposition (PVD), and improve lubrication and mechanical characteristics at the same time by adding copper (Cu) in a CrN coating material. Further, the surface treatment method may not require an interlayer or bonding layer due to substantially improved adhesion with a base material. Moreover, the surface treatment method features minimizing cost increase by using a high sputtering ratio of Cr and Cu, and increasing mass-productivity by using a chromium (Cr)-copper (Cu) composite target.

According to an exemplary embodiment of the present invention, a surface treatment method may comprise: preparing a composite comprising chromium (Cr) and copper (Cu); and forming a coating layer comprising chromium (Cr)-copper (Cu)-nitrogen (N) by sputtering the composite in a nitrogen-containing atmospheric gas. Preferably, the composite may comprise Cr of about 95 to 98 atomic percents and Cu of about 2 to 5 atomic percents, the atomic percents with respect to the total number of atoms of the composite. Preferably, the coating layer may comprise Cr of about 30 to 40 atomic percents, Cu of about 2 to 5 atomic percents, and N constituting the balance of the atoms of the coating layer, the atomic percents with respect to the total number of atoms of the coating layer.

The composite, as used herein, can be a simple admixture of the components or materials as described above.

The composite coating may preferably include nanoparticles or nanocrystallines of Cr—Cu—N composite material, which may suitably having a size of about 10 nm or less. It would be understood that such composite coating may also be referred to as “nano-composite coating”.

In the forming the coating layer comprising Cr—Cu—N, chromium (Cr) may be deposited as CrₓN₁₋ₓ(0.3≦x≦0.4) by unbalanced closed field magnetron sputtering (UBCFMS) in argon- and nitrogen-containing atmospheric gas.

The sputtering may be performed at a sputter power of about 10 to 14 W.

The sputtering may be performed at a pressure of about 3×10⁻³ to 4×10⁻³ mBar.

The sputtering may be performed at a bias of about 100 to 150V.

The sputtering may be performed at a ratio of Ar:N₂ in the atmospheric gas of about 1:3 to 5.

Further, provided is a composite coating layer that may be manufactured by the method described herein.

Still further, provided is a vehicle part that comprises a composite coating layer manufactured by the method described herein. Exemplary vehicle part may include, but not limited to, a engine driving part of vehicles.

As such, the surface treatment method according to various exemplary embodiments of the present invention may be widely utilized in forming a chromium (Cr)-copper (Cu)-nitrogen (N) coating layer on a surface of vehicle engine driving parts, or the like.

Other aspects of the present invention are disclosed infra.

### BRIEF DESCRIPTION OF THE DRAWINGS

The above and other objects, features and advantages of the present invention will be more apparent from the following detailed description taken in conjunction with the accompanying drawings.

FIG. 1 shows a exemplary mass-production coating process and apparatus used in an exemplary surface treatment method according to an exemplary embodiment of the present invention.

FIG. 2 shows exemplary graphs of characteristics (coefficient of friction, hardness, and adhesion) of an exemplary coating material measured by varying copper (Cu) contents of an exemplary composite coating layer manufactured by an exemplary surface treatment method according to an exemplary embodiment of the present invention.

FIG. 3 shows exemplary graphs of comparison results between an exemplary coated product manufactured by an exemplary surface treatment method according to an exemplary embodiment of the present invention and a product conventionally manufactured in the related art using diamond like carbon (DLC), in view of mechanical characteristics and time required for a coating process.

FIG. 4 shows cross-sectional microscopic views by a transmission electron microscope (TEM) of an exemplary coating layer manufactured by an exemplary surface treatment method according to an exemplary embodiment of the present invention.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles. The terminology used herein is for the purpose of describing particular exemplary embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

Hereinafter, a method for surface treatment with superior mass-productivity and low friction characteristics according to various exemplary embodiments of the present invention is described with reference to the accompanying drawings.

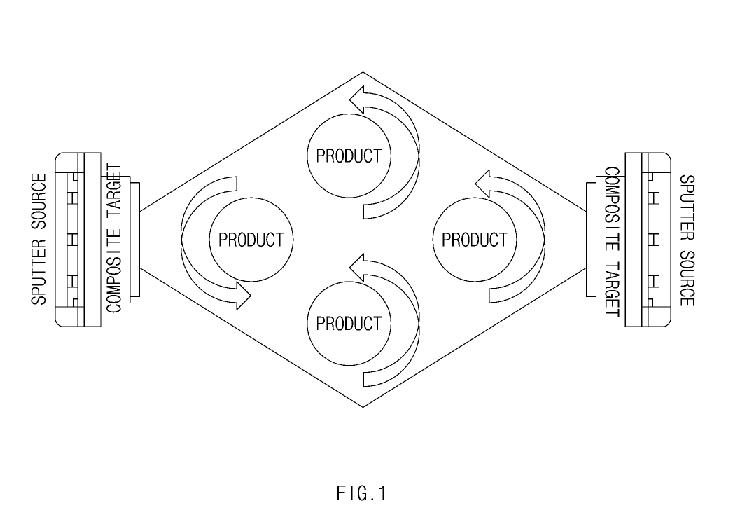

A chromium (Cr)-copper (Cu) composite is manufactured using a sintering process. The Cr—Co composite may comprise Cr of about 95 to 98 atomic percents and Cu of about 2 to 5 atomic percents, the atomic percents with respect to the total number of atom of the composite. The Cr—Co composite may be used for a general mass-production coating equipment in which there is no limitation in a coating region in a chamber as shown in FIG. 1, and thus coating for a number of products in one batch can be achieved to provide superior mass-productivity.

When a conventional hybrid physical vapor deposition (PVD) method is performed for coating, the composition of the coating may be easily adjusted; however, when two or more source elements are co-deposited at the same time, a coated area may be reduced small, which may deteriorate mass-productivity. According to the present invention, superior characteristics of a coating material that can be obtained by the conventional hybrid PVD method may be provided and at a same time, mass-production may be achieved.

The following Table 1 shows exemplary conditions of a sputtering process according to an exemplary embodiment of the present invention.

TABLE 1

| | Sputter | Process | | Ar:N₂ |
|---|---|---|---|---|
| Process Factors | Power | pressure | Bias | Ratio |
| Condition Scope | 10~14 W | 3~4 × 10⁻³ mBar | 100~150 V | 1:3~5 |

Preferably, when the Cr—Cu composite is manufactured, and an unbalanced closed field magnetron sputtering (UBCFMS) process may be performed by using the conventional mass-production coating process equipment under process conditions as shown in Table 1, thus obtained coating layer may have decreased lubrication coefficient of friction, increased hardness/close adhesion, and reduced time required for coating, thereby providing superior productivity and qualities as compared to the conventional surface treatment method.

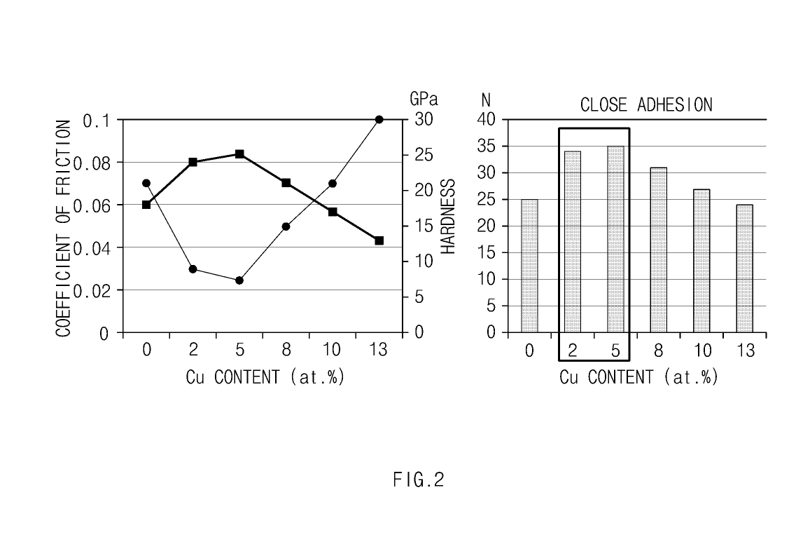

The present inventors found that lubrication and mechanical characteristics such as coefficient of friction, hardness and close adhesion could vary according to copper (Cu) content included in the coating layer, and evaluated various physical characteristics by changing copper (Cu) content to confirm the above discovery. Results thereof are shown in the following FIG. 2.

As shown in FIG. 2, it is preferred that Cu content in the coating layer is of about 2 to 5 atomic percents with respect to the total number of atoms of the coating layer. When the coating is formed by adding Cu having the above-described range, adhesion characteristic may be substantially improved by solving residual stress due to the addition of Cu, hardness characteristic may be substantially improved superior due to an increased solid solution strengthening effect, and lubrication characteristic may also be maximized due to a low friction element Cu.

### EXAMPLE

Hereinafter, characteristics of the coating material are shown after testing according to contents for each element of the coating layer including Cr, through Examples.

### Example 1

### Confirmation of Difference in Characteristics for Each Content of Coating Layer

Chromium (Cr)-copper (Cu)-nitrogen (N) coating layers were formed by using the above-described process, and characteristics of the coating materials were tested according to contents of Cu and Cr. Results thereof were shown in Table 2 below.

TABLE 2

| | | Characteristics of Coating Material | | |
|---|---|---|---|---|
| | | | | Close |
| Content for each element (at. %) | | Coefficient | Hardness | Adhesion |
| Cu | Cr | of Friction | (GPa) | (N) |
| <2 | — | <0.07 | 18 | ~25 |
| | <30 | 0.07~0.04 | 21 | ~30 |
| 2~5 | 30~40 | 0.025~0.03 | 24~25 | 34~35 |
| | >45 | 0.05~0.035 | | ~31 |
| >5 | — | >0.05 | 21 | <27 |

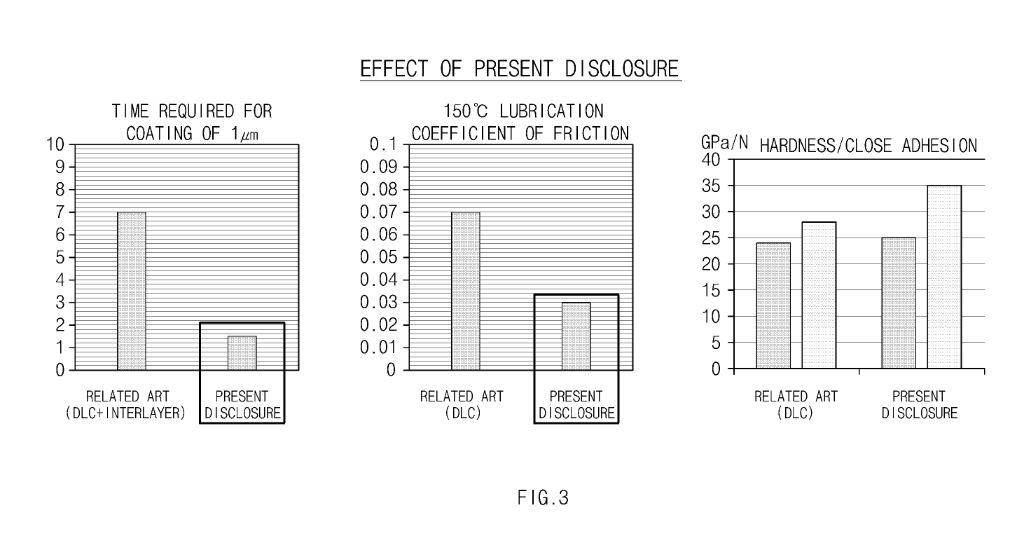

As shown in Table 2, when Cu was included in a content of 2 to 5 percents by atom, and Cr was included a content of 30 to 40 atomic percents with respect to the total number of atoms in the coating layer, hardness and close adhesion had the greatest value, and coefficient of friction had the smallest value. When considering that a coefficient of friction of DLC is 0.06-0.07, the coefficient of friction of the present invention was decreased to about half as that of DLC in a case of using the surface treatment method according to the present invention. In addition, when the coating material of the present invention includes Cr of about 30 to 40 atomic percents and Cu of about 2 to 5 atomic percents with respect to the total number of atoms in the coating layer, time required for coating of 1 μm may be reduced to be about ⅕ times as compared to DLC, and hardness and close adhesion may be also slightly improved as compared to the DLC. FIG. 3 shows a graph specifically showing comparison between the exemplary coating according to an exemplary embodiment of the present invention and DLC of conventional coating in view of physical characteristics.

As such, Cu may be suitably contained in about 2 to 5 atomic percents with respect to the total number of atoms in the coating layer. When a content of Cu is less than 2 atomic percents, hardness characteristic may be improved in some extent due to a solid solution strengthening effect of Cu; however, adhesion property may not be improved due to residual stress of dominantly formed CrN coating materials, and lubrication characteristic may not be sufficient due to insufficient content of a low friction element Cu. In addition, when a coating material contains Cu of greater than about 5 atomic percents, hardness characteristic may be deteriorated due to high content of Cu, and lubrication characteristic may also be deteriorated due to reduction of load-bearing capacity. Further, Cu imbalance may occur in the coating material due to surface diffusion of Cu, such that characteristics of the coating material may be deteriorated and close adhesion may be reduced.

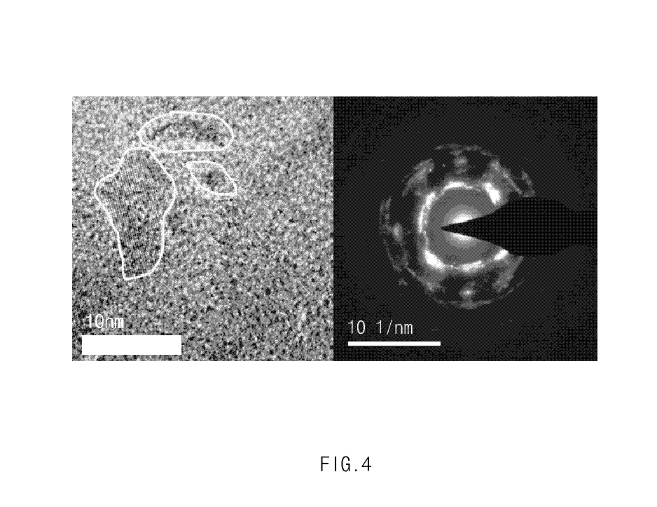

In addition, a cross-section of the coating material obtained by using the surface treatment method according to the present invention was analyzed by using a transmission electron microscope (TEM), and results thereof were shown in FIG. 4.

As shown in FIG. 4, a nano-composite structure including amorphous nanocrystalline having a size of about 10 nm or less in combination way could be confirmed, such that high mechanical characteristic, and low friction, thermal resistance characteristic, and the like, may be implemented at the same time.

When surfaces of the driving parts such as an engine, and the like, are coated with the composite composition comprising Cr, Co and N by the surface treatment method according to various exemplary embodiments of the present invention as described above, improved adhesion with a base material as well as superior lubrication and mechanical characteristics may be obtained, and time required for a coating process may be reduced, such that the coating material may be mass-produced.

What is claimed is:

1. A method for surface treatment, comprising:
preparing a composite comprising chromium (Cr) and copper (Cu) composite; and
forming a coating layer comprising chromium (Cr), copper (Cu), and nitrogen (N) by sputtering from the composite in a nitrogen-containing atmospheric gas.

2. The method of claim 1, wherein the composite comprises Cr of about 95 to 98 atomic percents and Cu of about 2 to 5 atomic percents, the atomic percents with respect to the total number of atoms of the composite.

3. The method of claim 1, wherein the coating comprises Cr of about 30 to 40 atomic percents, Cu of about 2 to 5 atomic percents, and N constituting the balance of the atoms of the coating layer, the atomic percents with respect to the total number of atoms of the coating layer.

4. The method of claim 1, wherein in the forming of the coating layer, chromium (Cr) is deposited as CrₓN₁₋ₓ(0.3≦x≦0.4) by unbalanced closed field magnetron sputtering (UBCFMS) in argon- and nitrogen-containing atmospheric gas.

5. The method of claim 1, wherein the sputtering is performed at a sputter power of about 10 to 14 W.

6. The method of claim 1, wherein the sputtering is performed at a pressure of about 3×10⁻³ to 4×10⁻³ mBar.

7. The method of claim 1, wherein the sputtering is performed at a bias of about 100 to 150V.

8. The method of claim 1, wherein the sputtering is performed at a ratio of Ar:N₂ in the atmospheric gas of about 1: about 3 to 5.

9. The method of claim 1, wherein the coating layer comprises nanoparticles or nanocrystallines having a size of about 10 nm or less.

10. A coating layer that is manufactured by a method of claim 1.

11. A vehicle part that is manufactured by a method of claim 1.

12. The vehicle part of claim 11, wherein the vehicle part is an engine driving part.
